(19) United States
(12) Patent Application Publication
(10) Pub. No.: US 2005/0201194 A1
(43) Pub. Date: Sep. 15, 2005

(54) Data processing system, data processing method, and data processing program

(75) Inventors: Kenji Sato, Tokyo (JP); Takahiro Ikeda, Tokyo (JP); Satoshi Nakazawa, Tokyo (JP)

Correspondence Address: SUGHRUE MION, PLLC, 2100 PENNSYLVANIA AVENUE, N.W., SUITE 800, WASHINGTON, DC, 20037, US

(73) Assignee: NEC CORPORATION

(21) Appl. No.: 11/077,127

(22) Filed: Mar. 11, 2005

(30) Foreign Application Priority Data
Mar. 12, 2004 (JP) 71762/2004

(51) Int. Cl. G11C 8/00

(52) U.S. Cl. 365/233

(57) ABSTRACT

A data processing system 30 includes a memory 61 storing at least one item of data as stored data, a data extracting section 32 connected to the memory 61, a data retrieving section 33 connected to the memory 61, and a set operation section 39. The data extracting section 32 extracts first data from data used in a first application. The set operation section 39 executes a set operation upon the first data and the stored data to produce operation result data representative of a result of the set operation. The data retrieving section 33 delivers the operation result data to a second application.

This application claims priority to prior Japanese patent application JP 2004-71762, the disclosure of which is incorporated herein by reference.

### BACKGROUND OF THE INVENTION

This invention relates to a data processing system and, in particular, to a data processing system, a data processing method, and a data processing program for use in transferring data among a plurality of application software parts.

A so-called “clipboard” is used to transfer data between applications or in a document. The clipboard serves to temporarily store data selected from the document. The data to be stored may be text (character string) data, graphic data, spreadsheet data, file data, and so on.

Referring to FIG. 1, an existing data processing system using such a clipboard will be described. The data processing system comprises a temporary memory (clipboard) 101, a data extracting section 102, a data retrieving section 103, and a retrieval object designating section 104. The data extracting section 102 extracts, from data used in an application, a specified range of data as extracted data and delivers the extracted data to the temporary memory 101. The temporary memory 101 stores the extracted data as stored data. The above-mentioned operation is executed in response to a “copy” command or a “cut” command entered by a user. The data retrieving section 103 reads the stored data in the temporary memory 101 and puts the stored data into a different application (or into a different place in a same document). The above-mentioned operation is executed in response to a “paste” command entered by the user. The extracted data transferred to the temporary memory 101 and stored in the temporary memory 101 as the stored data is kept stored therein until a different data is extracted and transferred to the temporary memory 101. Therefore, the data retrieving section 103 (i.e., the user) can retrieve (paste) the same data repeatedly.

In case where the temporary memory 101 is adapted to store only a single item of data, originally stored data is replaced by the different data newly transferred. In case where the temporary memory 101 is adapted to store multiple items of data, the stored data is kept stored even if the different data is newly transferred. In the latter case, the retrieval object designating section 104 illustrated in FIG. 1 selects one of the multiple items of data stored in the temporary memory 101. The data retrieving section 103 executes the above-mentioned retrieving operation in response to designation by the retrieval object designating section 104.

Japanese Patent Application Publication (JP-A) No. H7-6170 (corresp. to U.S. Pat. No. 5,659,791) discloses a method of encapsulating an extracted part of a document into an object. The method is implemented by a data processing system including a video display, a memory for storing objects, and at least one processor for running an object-oriented operating system. The method comprises the steps of (a) displaying a portion of a document on the video display, (b) selecting, from the portion of the document displayed on the video display, information to be extracted, (c) extracting the selected information from the document, and (d) encapsulating the selected information into an object stored in the memory.

Japanese Patent Application Publication (JP-A) No. H11-306177 discloses a technique aimed at providing a character string storing/retrieving device capable of easily selecting a desired one of a plurality of character strings stored in a clipboard. Herein, the character strings include a character string indicative of URL (Uniform Resource Locator), a character string indicative of an e-mail address, and so on. The character string storing/retrieving device comprises character string storing means capable of storing a plurality of character strings, registering means responsive to a registration request for making the character string storing means store a character string, retrieving means responsive to a retrieval request for retrieving the character string, character string type discriminating means for discriminating the type of the character string, and output means for outputting the retrieved character string in a form according to the discriminated type.

### SUMMARY OF THE INVENTION

It is an object of this invention to provide a data processing system, a data processing method, and a data processing program capable of transferring information necessary and sufficient for a user between applications.

It is another object of this invention to provide a data processing system, a data processing method, and a data processing program capable of reducing a number of steps of a set operation process for list data.

In the following, reference numerals used in the description of the preferred embodiments are affixed in parentheses merely for the purpose of facilitating understanding of this invention. Those reference numerals shall not be used to interpret the technical scope of the invention set forth in the appended claims.

A data processing system (30, 40, 50) according to the present invention comprises a memory (61) for storing at least one item of data as stored data, a data extracting section (32, 42, 52) connected to the memory (61), a data retrieving section (33, 43, 53) connected to the memory (61), and a set operation section (39, 49, 59). The data extracting section (32, 42, 52) extracts first data from data used in a first application. The set operation section (39, 49, 59) executes a set operation upon the first data and the stored data to produce operation result data representative of a result of the set operation. The data retrieving section (33, 43, 53) delivers the operation result data to a second application.

In the data processing system (30) according to this invention, the set operation section (39) is connected to the data extracting section (32). In this case, the data extracting section (32) reads one item of stored data from the memory (61) and delivers the first data and the one item of stored data to the set operation section (39). After the set operation section (39) executes the set operation, the data extracting section (32) is supplied with the operation result data from the set operation section (39) and delivers the operation result data to the memory (61). The data retrieving section (33) reads the operation result data from the memory (61) and delivers the operation result data to the second application.

In the data processing system (40) according to this invention, the memory (61) memorizes a plurality of items of stored data. The set operation section (49) is connected to the data extracting section (42). In this case, the data extracting section (42) reads at least one item of stored data from the memory (61) and delivers the first data and the at least one item of stored data to the set operation section (49). Herein, the data extracting section (42) may read, among a plurality of items of stored data, a latest item of stored data and deliver the first data and the latest item of stored data to the set operation section (49). After the set operation section (49) executes the set operation, the data extracting section (42) is supplied with the operation result data from the set operation section (49) and delivers the operation result data to the memory (61). Herein, the memory (61) may store the operation result data supplied thereto as a new item of stored data in addition to the stored data. Alternatively, the memory (61) may store the operation result data supplied thereto in place of the at least one item of stored data. The data retrieving section (43) reads the operation result data from the memory (61) and delivers the operation result data to the second application.

In the data processing system (50) according to this invention, the memory (61) stores a plurality of items of stored data. The set operation section (49) is connected to the data retrieving section (53). In this case, the data extracting section (52) delivers the first data as one of the items of stored data to the memory (61). The data retrieving section (53) reads multiple items of stored data from the memory (61) and delivers the multiple items of stored data to the set operation section (59). Herein, the data retrieving section (53) may read all items of stored data from the memory (61) and deliver the all items of stored data to the set operation section (59). After the set operation section (59) executes the set operation, the data retrieving section (53) is supplied with the operation result data from the set operation section (59) and delivers the operation result data to the second application.

In the above-mentioned data processing system (30, 40, 50), the set operation is one of a union set operation, an intersection set operation, an exclusive-OR set operation, and a difference set operation. The data processing system (30, 40, 50) may further comprise an attribute designating section (35, 45, 55) connected to the set operation section (39, 49, 59). The attribute designating section (35, 45, 55) designates, as an object of the set operation, one of a plurality of attributes of the stored data. For example, the stored data may be a plurality of words (word list). In this case, the above-mentioned attributes include at least one of a character string of a word, a function of the word, a pronunciation of the word, an inflected form of the word, and a syntactic dependency of the word.

Thus, by the data processing system (30, 40, 50) according to this invention, it is possible to easily execute the set operation upon the data transferred between the first and the second applications. In order to execute the set operation, it is unnecessary to start a different application for executing the set operation and to transfer the data to the different application. Therefore, the number of steps of a set operation process for list data can be reduced. Further, information necessary and sufficient for a user is transferred between the first and the second applications.

A data processing system (10) according to this invention comprises a memory (61), a data extracting section (12) connected to the memory (61), a data retrieving section (13) connected to the memory (61), and an attribute designating section (15) connected to the data extracting section (12). The data extracting section (12) extracts first data from held data used in a first application and delivers the first data to the memory (61). The data retrieving section (13) reads the first data from the memory (61) and delivers the first data to a second application. The attribute designating section (15) designates, among a plurality of attributes of the held data, at least one attribute of the first data.

A data processing system (20) according to this invention comprises a memory (61), a data extracting section (22) connected to the memory (61), a data retrieving section (23) connected to the memory (61), and an attribute designating section (25) connected to the data retrieving section (23). The data extracting section (22) extracts first data from held data used in a first application and delivers the first data to the memory (61). The data retrieving section (23) extracts second data from the first data stored in the memory (61) and delivers the second data to a second application. The attribute designating section (25) designates, among a plurality of attributes of the first data, at least one attribute of the second data. For example, the first data represents a plurality of words (word list). In this case, the above-mentioned attributes include at least one of a character string of a word, a function of the word, a pronunciation of the word, an inflected form of the word, and a syntactic dependency of the word.

Thus, by the data processing system (10, 20, 30, 40, 50) according to this invention, it is possible to select desired data to be transferred. Specifically, by designating a necessary “attribute” or “attributes” alone, information necessary and sufficient for a user is transferred between the first and the second applications.

A data processing method according to this invention includes the steps of (A) extracting first data from data used in a first application, (B) reading at least one item of stored data from a memory (61), (C) executing a set operation upon the first data and the at least one item of stored data, (D) storing in the memory (61) operation result data representative of a result of the set operation, and (E) reading the operation result data from the memory (61) and delivering the operation result data to a second application. The step (D) of storing the operation result data includes a step of adding the operation result data as a new item of stored data. Alternatively, the step (D) of storing the operation result data includes a step of replacing the at least one item of stored data by the operation result data.

A data processing method according to this invention includes the steps of (F) extracting first data from data used in a first application, (G) storing the first data in a memory (61) as one of a plurality of items of stored data, (H) reading multiple items of stored data from the memory (61), (I) executing a set operation upon the multiple items of stored data read in the step (H), and (J) delivering to a second application operation result data representative of a result of the set operation.

The data processing method according to this invention may further include the step (Z) of designating, among a plurality of attributes of the stored data, an attribute as an object of the set operation.

A data processing method according to this invention includes the steps of (K) designating at least one attribute among a plurality of attributes of held data used in a first application, (L) extracting from the held data first data having the at least one attribute, (M) storing the first data in a memory (61), and (N) reading the first data stored in the memory (61) and delivering the first data to a second application.

A data processing method according to this invention includes the steps of (O) extracting first data from held data used in a first application, (P) storing the first data in a memory (61), (O) designating at least one attribute among a plurality of attributes of the first data, (R) extracting from the first data stored in the memory (61) second data having the at least one attribute, and (S) delivering the second data to a second application.

The above-mentioned data processing system may be implemented by a computer and a computer program. In this case, a data processing system (60) comprises the above-mentioned memory (61) and an arithmetic operation unit (65) connected to the memory (61). The data processing method mentioned above is described in a data processing program as a computer program. The data processing program is executed by the arithmetic operation unit (65).

With the data processing system, the data processing method, and the data processing program according to this invention, it is possible to transfer information necessary and sufficient for a user between applications.

With the data processing system, the data processing method, and the data processing program according to this invention, it is possible to reduce the number of steps of a set operation process upon list data.

### BRIEF DESCRIPTION OF THE DRAWINGS

FIG. 1 is a block diagram showing an existing data processing system;

FIG. 2 is a block diagram showing a data processing system according to a first embodiment of this invention;

FIG. 3 is a flow chart for describing a data processing method according to the first embodiment of this invention;

FIG. 4 is a block diagram showing a data processing system according to a second embodiment of this invention;

FIG. 5 is a block diagram showing a data processing system according to a third embodiment of this invention;

FIG. 6 is a flow chart for describing a data processing method according to the third embodiment of this invention;

FIG. 7 is a block diagram showing a data processing system according to a fourth embodiment of this invention;

FIG. 8 is a flow chart for describing a data processing method according to the fourth embodiment of this invention;

FIG. 9 is a block diagram showing a data processing system according to a fifth embodiment of this invention;

FIG. 10 is a flow chart for describing a data processing method according to the fifth embodiment of this invention;

FIG. 11 is a block diagram showing a data processing system according to a sixth embodiment of this invention;

FIG. 12 is a view showing an example of attribute values used in the embodiments of this invention; and

FIG. 13 is a view showing an example of data is stored in a temporary memory in the embodiments of this invention.

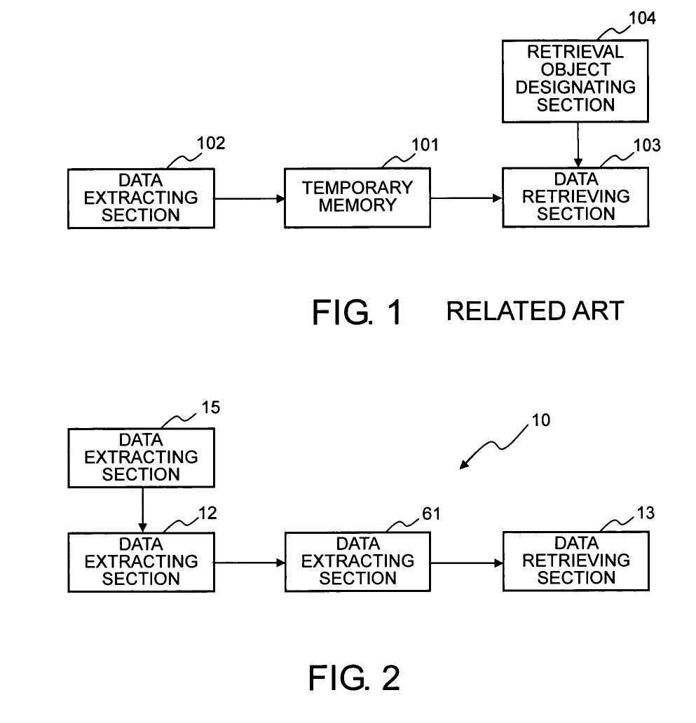

### DESCRIPTION OF THE PREFERRED EMBODIMENTS

Now, description will be made of several preferred embodiments of this invention with reference to the drawing.

### First Embodiment

Referring to FIG. 2, a data processing system 10 according to a first embodiment of this invention comprises a data extracting section 12, a data retrieving section 13, a temporary memory 61, and an attribute designating section 15. The temporary memory 61 temporarily stores data such as text (character string) data, graphic data, spreadsheet data, and file data. The data extracting section 12 extracts, as extracted data, a predetermined range of data from data used in an application and delivers the extracted data to the temporary memory 61. The above-mentioned operation is executed in response to a “copy” or a “cut” command entered by a user. The data retrieving section 13 reads the data stored in the temporary memory 61 and delivers the data to another application. The above-mentioned operation is executed in response to a “paste” command entered by the user.

In this invention, the above-mentioned “extracted data” may include not only the data itself but also “attribute values” (properties) of the data. The “attribute values” will be described with reference to FIG. 12. FIG. 12 shows “held data” held by a particular application A and the “attribute values” corresponding to the held data. By way of example, it is assumed that the application A performs a text mining operation. The text mining operation is a process of analyzing a text and automatically extracting information therefrom. The application A extracts words from an input text by dividing the input text into text segments by morphological analysis and removing ancillary words, such as particles and auxiliary verbs in Japanese and prepositions and articles in English, from the text segments. In this case, the held data held by the application A is text data.

For example, it is assumed that a sentence “he bought a gift for her” is entered. In this event, the application A hold “he”, “buy”, “gift”, “she” as the held data, as shown in FIG. 12. Herein, as illustrated in FIG. 12, each item of the held data has a “character string”, an “expression”, a “function”, an “inflected form (or tense)”, and a “syntactic dependency” as attribute values. For example, the data “he” has attribute values “he” as the character string, “he” as the expression, “noun” as the function, “−” as the inflected form, and “buy” as the syntactic dependency. The data “buy” has attribute values “buy” as the character string, “bought” as the expression, “verb” as the function, “past” as the inflected form, and “−” as the syntactic dependency.

According to the first embodiment, the attribute designating section 15 is connected to the data extracting section 12. The attribute designating section 15 designates the “attribute values” to be contained in the extracted data stored in the temporary memory 61. Specifically, when data is transferred from a particular application as a source application to another application as a destination application, “attribute values” used in the destination application can be designated by the attribute designating section 15. For example, the attribute designating section 15 selects and designates either “to be stored” or “not to be stored” for all kinds of the “attribute values”. In case where the transferred data is word data or text data, the attribute value “character string” may be set “to be stored” as a default.

The attribute values designated by the attribute designating section as “to be stored” may appropriately be selected by the user. Specifically, the attribute designating section 15 is interposed between the user and the data extracting section 12 and controls the function of the data extracting section 12 in accordance with a user's request. According to the “designation” by the attribute designating section 15, the data extracting section 12 produces the extracted data and delivers the extracted data to the temporary memory 61. Thus, the “attribute values” designated as “to be stored” by the attribute designating section 15 are stored in the temporary memory 61 as the extracted data together with the word. When the data retrieving section 13 reads the extracted data, all information stored in the temporary memory 61 is read. Thus, the “attribute values” necessary and sufficient are transferred between the applications.

When the user selects a plurality of words (hereinafter referred to as a word list) to be transferred to another application, the data extracting section 12 receives information associated with the words contained in the word list. For example, when the user selects the words “he” and “she” in the held data shown in FIG. 12, the data extracting section 12 receives information associated with “he” and “she” from the application. The information contains all “attribute values”.

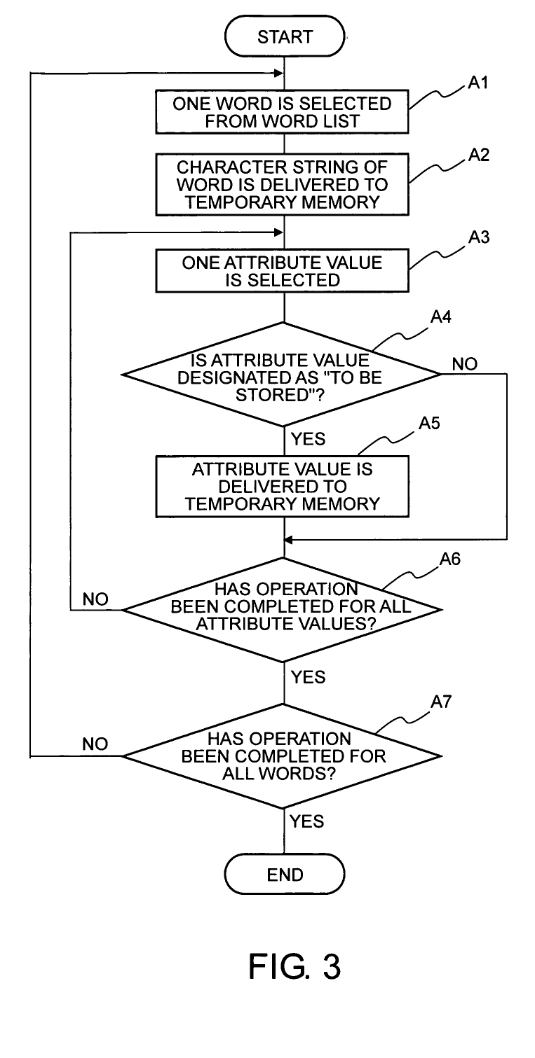

Referring to FIG. 3, the operation of the data extracting section 12 in the first embodiment will be described more in detail. For example, it is assumed that the attribute designating section 15 designates the attribute values “character string (default)” and the “function” as “to be stored” and other attribute values as “not to be stored”. At first, the data extracting section 12 selects one word from the word list (step A1). For example, the data extracting section 12 selects the word “he” from the word list. In case where the attribute value “character string” is designated as “to be stored” as a default, the data extracting section 12 delivers the character string of the selected word to the temporary memory 61 (step A2).

Next, with reference to the “designation” by the attribute designating section 15, the data extracting section 12 adds attribute value data to word data being processed. Specifically, the data extracting section 12 selects one of the “attribute values” of the word (step A3). For example, the attribute value “function” is selected. Then, the data extracting section 12 judges whether or not the selected attribute value is designated as “to be stored” (step A4). Since the attribute value “function” is designated as “to be stored” (yes in step A4), the data extracting section 12 delivers “noun” as the function of the word “he” to the temporary memory 61 as the attribute value (step A5). Consequently, the temporary memory 61 stores the data “he (function: noun)”.

In case where the selected attribute value is designated as “not to be stored” (no in step A4) or after the above-mentioned step A5, the data extracting section 12 selects a next “attribute value” (step A3). In this manner, similar processing is repeated for all of the “attribute values”. When the processing is completed for all “attribute values” (yes in step A6), the data extracting section 12 selects a next word from the word list (step A1). For example, the data extracting section 12 selects the word “she” from the word list. Similar processing is repeated for all words contained in the word list. When the processing is completed for all words (yes in step A7), the operation of the data extracting section 12 is completed.

At this time, the temporary memory 61 stores as the extracted data “he (function: noun)” and “she (function: noun)”. The data retrieving section 13 reads the extracted data and delivers the extracted data to another application. As another application, a thesaurus application is exemplified. Thus, the data (“he (function: noun)” and “she (function: noun)”) containing the character strings and the function information are transferred from the text mining application to the thesaurus application. The user can register these data in a thesaurus, for example, as “persons”.

In case where an object to be transferred between the applications is a word, the “attribute values” may be a “character string”, a “expression”, a “function”, a “pronunciation”, an “inflected form”, and a “syntactic dependency”. In case where the object is not a word, it is also possible to designate “attribute values”. For example, if the object is photographic data, the “attribute values” may be a “shooting date”, a “photographer”, and a “picture size”.

As described above, with the data processing system and the data processing method according to the first embodiment of this invention, it is possible to select desired data to be transferred. Thus, by designating the necessary “attribute values” alone, the information necessary and sufficient for the user is transferred between the applications.

### Second Embodiment

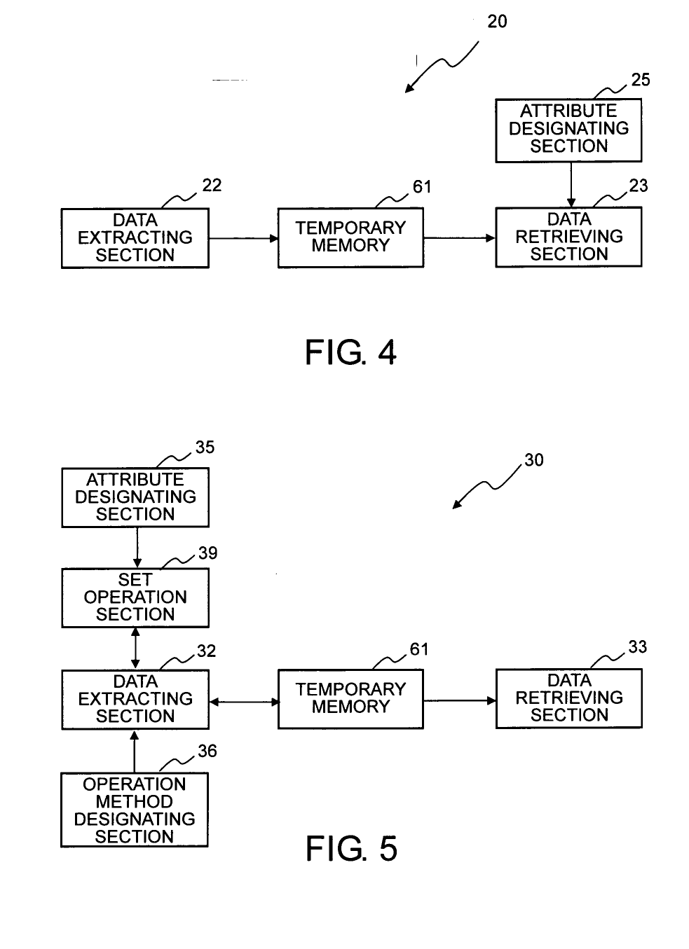

Referring to FIG. 4, a data processing system 20 according to a second embodiment of this invention comprises a data extracting section 22, a data retrieving section 23, a temporary memory 61, and an attribute designating section 25. The data extracting section 22 extracts, as extracted data, a predetermined range of data from data used in an application and delivers the extracted data to the temporary memory 61. The data extracting section 22 delivers, as the extracted data, the data containing all kinds of “attribute values”.

According to the second embodiment of this invention, the attribute designating section 25 is connected to the data retrieving section 23. The attribute designating section 25 designates the “attribute values” used in another application as a destination application. Following the “designation” by the attribute designating section 25, the data retrieving section 23 reads (extracts) desired data alone from the extracted data. For example, the attribute designating section 25 selects and designates either “to be read” or “not to be read” for all kinds of the “attribute values”. In case where the transferred data is word data or text data, the attribute value “character string” may be set “to be read” as a default.

Referring to FIG. 12, a data processing method according to this embodiment will be described. In the manner similar to that described in conjunction with the first embodiment, if the user selects the word list “he” and “she” in a particular application, the data extracting section 22 receives information associated with the word list. Then, the data extracting section 22 delivers the information as the extracted data to the temporary memory 61. The extracted data contains all “attribute values”.

Next, according to the “designation” by the attribute designating section 25, the data retrieving section 23 reads the data via the steps similar to those illustrated in FIG. 3. For example, the attribute designating section 25 designates the attribute values “character string (default)” and “function” as “to be read” and other attribute values as “not to be read”. In this case, the data retrieved by the data retrieving section 23 from the temporary memory 61 is the data “he (function: noun)” and “she (function: noun)”. The data retrieving section 23 delivers the data to another application such as a thesaurus application.

As described above, with the data processing system and the data processing method according to the second embodiment of this invention, it is possible to select desired data to be transferred. In other words, by designating the necessary “attribute values” alone, the information necessary and sufficient for the user is transferred between the applications.

### Third Embodiment

Referring to FIG. 5, a data processing system 30 according to a third embodiment of this invention comprises a data extracting section 32, a data retrieving section 33, a temporary memory 61, an attribute designating section 35, an operation method designating section 36, and a set operation section 39.

In this embodiment, the data extracting section 32 executes a predetermined operation upon the extracted data and then delivers data representative of a result of the predetermined operation to the temporary memory 61. Specifically, a set operation is executed upon the extracted data and data stored in the temporary memory 61 (hereinafter referred to as “stored data”). The operation method designating section 36 is connected to the data extracting section 32 and designates a method of the set operation. The method of the set operation may be a union set operation, an intersection set operation, an exclusive-OR set operation, a difference set operation, and so on. The operation method designating section 36 is interposed between the user and the data extracting section 32 and controls the function of the data extracting section 32 in accordance with a user's request.

The data extracting section 32 acquires the extracted data and simultaneously reads the stored data from the temporary memory 61. The data extracting section 32 delivers to the set operation section 39 the extracted data, the stored data, and information related to the operation method designated by the operation method designating section 36. In accordance with the designated operation method, the set operation section 39 executes the set operation upon the extracted data and the stored data supplied thereto. Thereafter, the set operation section 39 returns data representative of a result of the set operation (hereinafter referred to as “operation result data”) to the data extracting section 32. Thus, the set operation section 39 takes a role as a subroutine.

The data extracting section 32 receives the operation result data and delivers the operation result data to the temporary memory 61. The above-mentioned series of operations by the data extracting section 32 are executed in response to a “copy” or a “cut” command entered by the user. In case where the temporary memory 61 is adapted to store a single item of data, originally stored data is replaced by the operation result data. The data retrieving section 33 reads the data stored in the temporary memory 61 and delivers the data to another application. The above-mentioned operation is executed in response to a “paste” command entered by the user.

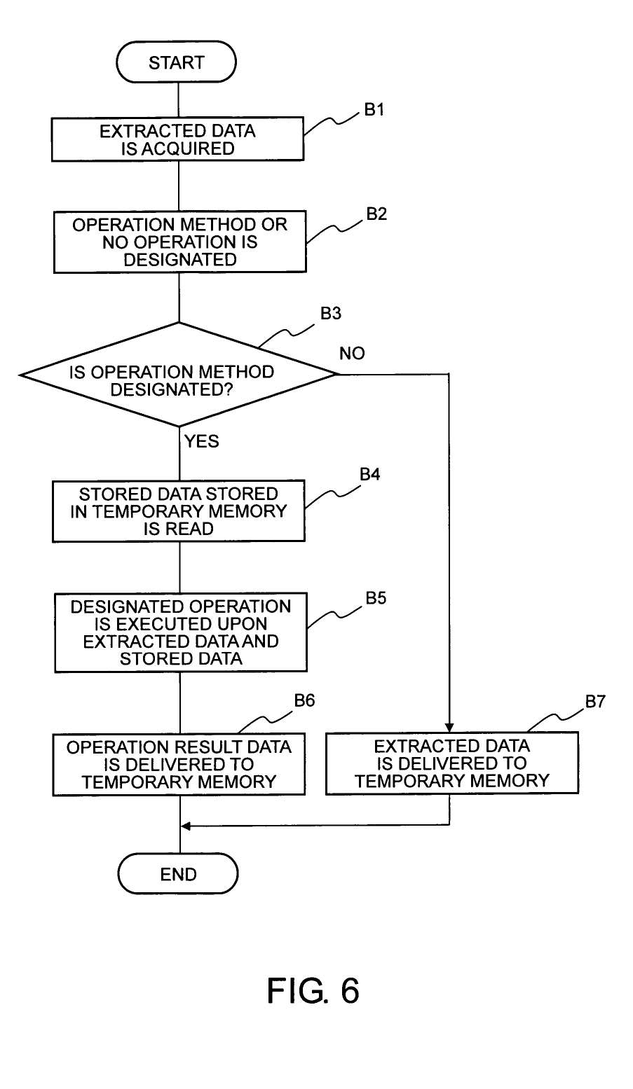

Referring to FIGS. 6, 12, and 13, the operation of the data processing system 30 according to the third embodiment of this invention will be described in detail.

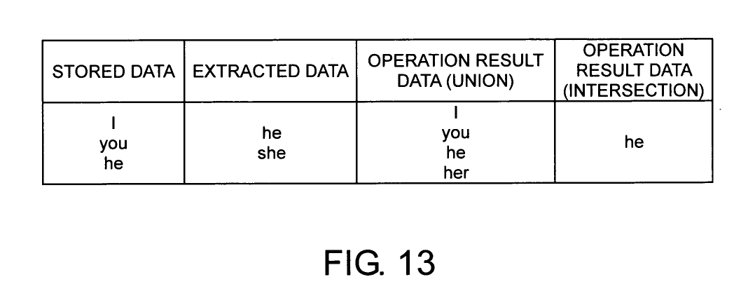

It is assumed that the temporary memory 61 stores list data “I, you, he” (word list) as the stored data, as illustrated in FIG. 13. It is also assumed that the user selects “he, she” from the held data illustrated in FIG. 12. In this event, the data extracting section 32 acquires the extracted data representative of the word list “he, she” as illustrated in FIG. 13 (step B1).

Next, according to the user's request, the operation method designating section 36 designates one of the operation methods including the union set operation, the intersection set operation, the exclusive-OR set operation, the difference set operation, and the like and informs the designated operation method to the data extracting section 32 (step B2). The operation method designating section 36 may not designate the operation method. In this event, (no in step B3), the data extracting section 32 directly delivers the extracted data “he, she” to the temporary memory 61 without executing the set operation (step B7).

In case where a particular operation method is designated (yes in step B3), the data extracting section 32 reads the stored data “I, you, he” from the temporary memory 61 (step B4). Next, the data extracting section 32 delivers to the set operation section 39 the extracted data, the stored data, and the information designating the operation method. Then, the set operation section 39 executes the set operation upon the extracted data “he, she” and the stored data “I, you, he” in accordance with the designated operation method (step B5).

For example, in case where the union set operation is designated, the set operation section 39 produces the operation result data representative of “I, you, he, she” as illustrated in FIG. 13. In case where the intersection set operation is designated, the set operation section 39 produces the operation result data representative of “he”. Thereafter, the set operation section 39 returns the operation result data to the data extracting section 32 and the data extracting section 32 delivers the operation result data to the temporary memory 61 (step B6). The stored data (“I, you, he”) in the temporary memory 61 is replaced by the operation result data (for example, “I, you, he, she”). The data retrieving section 33 reads the operation result data and delivers the operation result data to another application such as a thesaurus.

Although the “character strings” of the words are compared in the above-mentioned set operation, other “attribute values” described in the first and the second embodiments may be taken into consideration. The “attribute values” considered upon the set operation are designated by the attribute designating section 35 connected to the set operation section 39. For example, it is assumed that particular word data has the “attribute values” including “character string” and “pronunciation”. In case where the attribute designating section 35 designates the attribute value “character string”, the set operation section 39 recognizes data “ [symbol] (pronunciation: ki-mi)” and data “ [symbol] (pronunciation: ku-n)” as same data. In case where the attribute designating section 35 designates the attribute value “pronunciation”, the set operation section 39 recognizes the data “ [symbol] (pronunciation: ki-mi)” and the data “ [symbol] (pronunciation: ku-n)” are recognized as different data.

For example, consideration will be made of the case where the intersection set operation is executed upon a word list “ [symbol] (pronuncation: kyo-), [symbol] (pronunciation: hashi), [symbol] [symbol] [symbol] (pronunciation: togetsu-kyou)” and a word list “ [symbol] (pronunciation: to), [symbol] (pronunciation: getsu), [symbol] (pronunciation: kyou)”. In this event, in case where the attribute value “character string” is designated, the operation result data “ [symbol] ” is obtained. On the other hand, in case where the attribute value “pronunciation” alone is designated, the operation result data “ [symbol] (pronunciation: kyou), [symbol] (pronunciation: hashi)” is obtained. Thus, a list of homophenes is obtained. As described above, the attribute designating section 35 designates, among the attributes of the stored data, the attribute as an object of the set operation.

With the data processing system and the data processing method according to the third embodiment, it is possible to easily execute the set operation for the data transferred between the applications. In order to execute the set operation, it is unnecessary to start a different application for executing the set operation and to transfer the data to the different application. Therefore, the number of steps of a set operation process for list data is reduced. Further, by the set operation, it is possible to add new data to the data transferred between the applications without duplication and to extract necessary data from the transferred data. Thus, the information necessary and sufficient for the user is transferred between the applications.

In this embodiment, the list data to be transferred is not restricted to the word list. As long as the set operation can be executed for the list data, this embodiment is applicable to any list. For example, a list of image data may be used in the data processing system according to this invention. In this case, the set operation is executed by judging matching/mismatching with respect to an image format, a resolution, an image size, or the like. It is therefore easy to organize the image data list.

### Fourth Embodiment

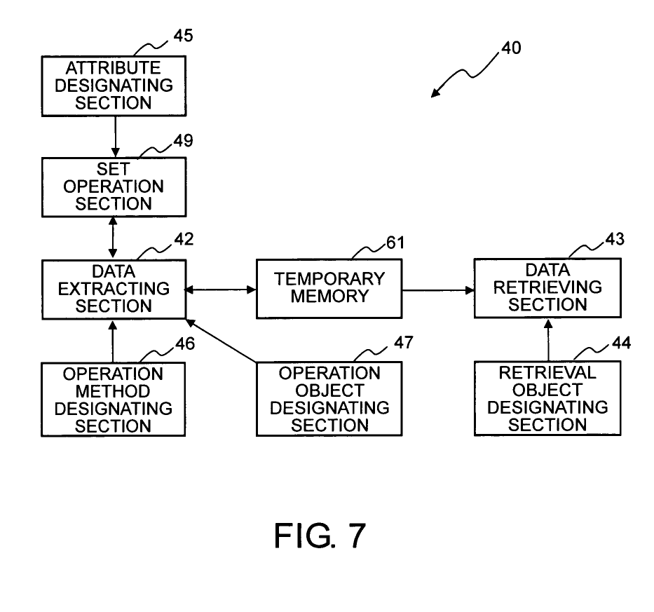

Referring to FIG. 7, a data processing system 40 according to a fourth embodiment of this invention comprises a data extracting section 42, a data retrieving section 43, a temporary memory 61, a retrieval object designating section 44, an attribute designating section 45, an operation method designating section 46, an operation object designating section 47, and a set operation section 49. The retrieval object designating section 44 and the operation object designating section 47 are connected to the data retrieving section 43 and the data extracting section 42, respectively.

In this embodiment, the temporary memory 61 stores a plurality of items of stored data. Therefore, upon executing the set operation similar to that described in conjunction with the third embodiment, the operation object designating section 47 designates, among those items of stored data stored in the temporary memory 61, one or multiple items of the stored data as an operation object. In accordance with the designation by the operation object designating section 47, the data extracting section 42 reads the stored data from the temporary memory 61. Further, the retrieval object designating section 44 designates the stored data to be read by the data retrieving section 43 from the temporary memory 61. In accordance with the designation by the operation object designating section 47, the data extracting section 42 reads the stored data from the temporary memory 61. The retrieval object designating section 44 designates the stored data read by the data retrieving section 43 from the temporary memory 61. In accordance with the designation by the retrieval object designating section 44, the data retrieving section 43 reads one or multiple items of stored data from the temporary memory 61.

The operation method designating section 46, the attribute designating section 45, and the set operation section 49 have functions similar to those of the operation method designating section 36, the attribute designating section 35, and the set operation section 39 in the third embodiment, respectively. The method of the set operation designated by the operation method designating section 46 may be a union set operation, an intersection set operation, an exclusive-OR set operation, a difference set operation, and so on.

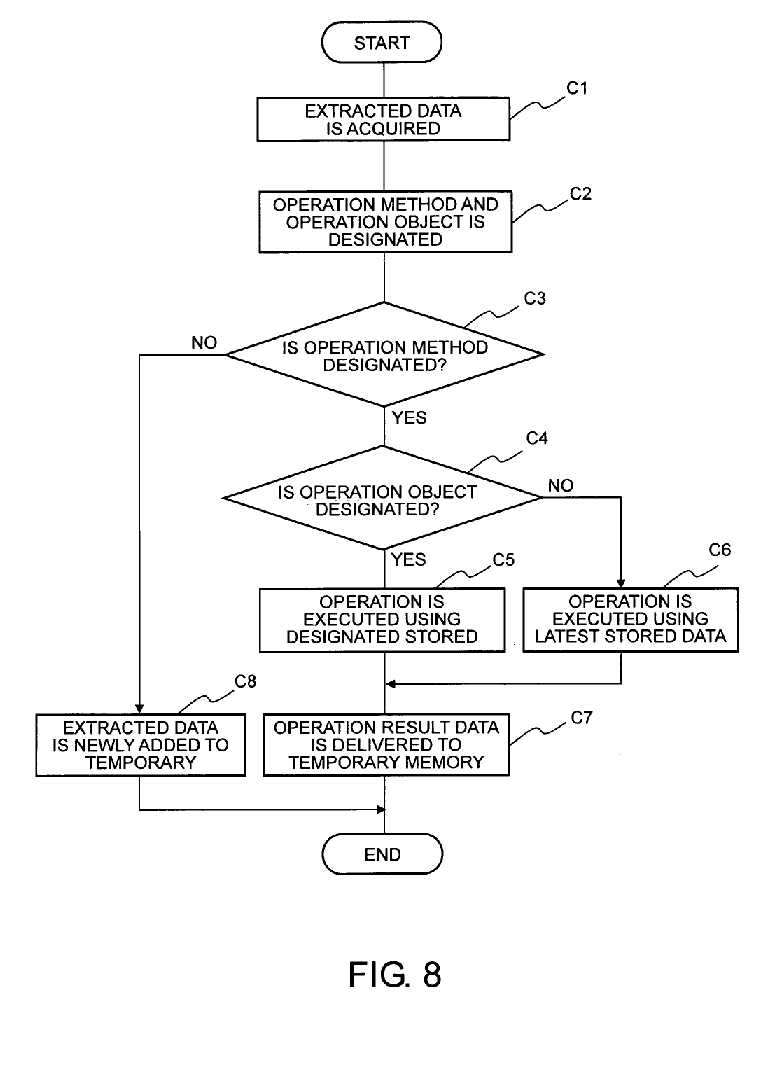

Referring to FIGS. 8, 12, and 13, the operation of the data processing system 40 in this embodiment will be described in detail.

It is assumed that the temporary memory 61 stores a first word list “I, you, he” and a second word list “I, he, they” as stored data. It is also assumed that the user selects “he, she” from the held data illustrated in FIG. 12. In this event, the data extracting section 42 acquires the extracted data representative of the word list “he, she” (step C1).

Next, according to the user's request, the operation object designating section 47 designates, among a plurality of items of stored data stored in the temporary memory 61, one or multiple items of stored data as an operation object. According to the user's request, the operation method designating section 46 designates one of the operation methods including the union set operation, the intersection set operation, the exclusive-OR set operation, the difference set operation, and so on and informs the designated operation method to the data extracting section 42 (step C2). The operation method designating section 46 may not designate the operation method. In this event (no in step C3), the data extracting section 42 directly delivers the extracted data “he, she” to the temporary memory 61 without executing the set operation. The extracted data is added to the temporary memory 61 as new stored data (step C8).

In case where a particular operation method is designated (yes in step C3) and the stored data as the operation object is designated (yes in step C4), the data extracting section 42 reads one or multiple items of stored data from the temporary memory 61. For example, the data extracting section 42 reads the stored data “I, you, he”. At this time, the data extracting section 42 delivers to the set operation section 49 the extracted data, the designated stored data, and the information designating the operation method. Then, the set operation section 49 executes the set operation upon the extracted data “he, she” and the designated stored data “I, you, he” in accordance with the designated operation method (step C5).

For example, in case where the union set operation is designated, the set operation section 49 produces the operation result data representative of “I, you, he, she” as illustrated in FIG. 13. In case where the intersection set operation is designated, the set operation section 49 produces the operation result data representative of “he”. Thereafter, the set operation section 49 returns the operation result data to the data extracting section 42 and the data extracting section 42 delivers the operation result data to the temporary memory 61 (step C7). The designated stored data (“I, you, he”) in the temporary memory 61 is replaced by the operation result data (for example, “I, you, he, she”).

In case where a particular operation method is designated (yes in step C3) and the stored data as the operation object is not designated (no in step C4), the data extracting section 42 reads a latest item of stored data from the temporary memory 61. For example, if the stored data “I, you, he” is the latest item of stored data, the data extracting section 42 reads the stored data “I, you, he”. Then, the set operation section 49 executes the set operation upon the extracted data “he, she” and the latest stored data “I, you, he” in accordance with the designated operation method (step C6). The operation result data is delivered to the temporary memory 61 (step C7). The latest item of stored data (“I, you, he”) is replaced by the operation result data (for example, “I, you, he, she”).

Alternatively, if the stored data as the operation object is not designated (no in step C4), the data extracting section 42 may read all items of stored data from the temporary memory 61. In this case, the extracted data “he, she” and all items of stored data “I, you, he” and “I, he, they” are subjected to the set operation. For example, if the union set operation is designated, the set operation section 49 produces the operation result data representative of “I, you, he, they, she”. If the intersection set operation is designated, the set operation section 49 produces the operation result data representative of “he”. The operation result data is stored in the temporary memory 61 as new stored data (step C7). Alternatively, after the data previously stored is erased, the operation result data is stored in the temporary memory 61 as new stored data.

After the operation result data is outputted as mentioned above, the data retrieving section 43 reads one item of stored data from the temporary memory 61 in accordance with the designation by the retrieval object designating section 44, and delivers the one item of stored data to another application such as a thesaurus application. Although the “character strings” of the words are compared in the above-mentioned example of the set operation, other “attribute values” may be taken into consideration in the manner similar to the third embodiment. The “attribute values” taken into consideration upon the set operation are designated by the attribute designating section 45 connected to the set operation section 49.

With the data processing system and the data processing method according to the fourth embodiment of this invention, it is possible to selectively and easily execute the set operation upon the data transferred between the applications. In order to execute the set operation, it is unnecessary to start a different application for executing the set operation and to transfer the data to the different application. Thus, the number of steps of the set operation process for the list data is reduced. Further, by the set operation, it is possible to add new data to the data transferred between the applications without duplication and to extract necessary data alone from the transferred data. Thus, the information necessary and sufficient for the user is transferred between the applications.

In this embodiment, the list data to be transferred is not limited to the word list. As far as the set operation can be executed for the list data, this embodiment is applicable to any list. For example, in a plurality of items of presentation data, it is possible to designate a “title” as the “attribute value” and thereafter designate the union set operation. In this manner, it is possible to easily obtain, from the presentation data, data as a combination of title pages alone.

### Fifth Embodiment

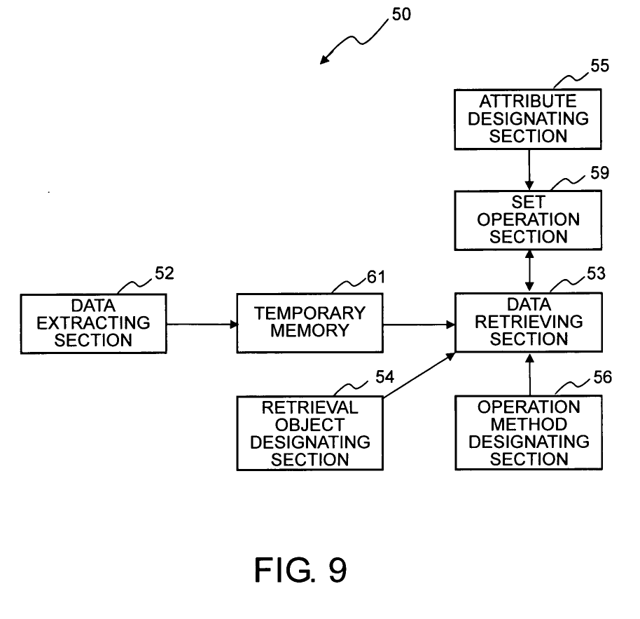

Referring to FIG. 9, a data processing system 50 according to a fifth embodiment of this invention comprises a data extracting section 52, a data retrieving section 53, a temporary memory 61, a retrieval object designating section 54, an attribute designating section 55, an operation method designating section 56, and a set operation section 59. The retrieval object designating section 54, the operation method designating section 56, and the set operation section 59 are connected to the data retrieving section 53.

In this embodiment, the temporary memory 61 stores a plurality of items of stored data. The retrieval object designating section 54 designates at least one item of stored data to be read by the data retrieving section 53 from the temporary memory 61. According to the designation by the retrieval object designating section 54, the data retrieving section 53 reads at least one item of stored data (retrieval object group) from the temporary memory 61.

According to this embodiment, the set operation is executed upon retrieving the stored data. The operation method designating section 56 designates a method of the set operation. The method of the set operation may be a union set operation, an intersection set operation, an exclusive-OR set operation, a difference set operation, and so on. The operation method designating section 56 is interposed between the user and the data extracting section 52 and controls the function of the data extracting section 52 in accordance with a user's request. The data retrieving section 53 delivers to the set operation section 59 the retrieval object group read as mentioned above and the information related to the designated operation method. According to the designated operation method, the set operation section 59 executes the set operation upon the retrieval object group supplied thereto. Thereafter, the set operation section 59 returns the operation result data representative of the operation result to the data extracting section 53. Thus, the set operation section 59 plays a role as a subroutine.

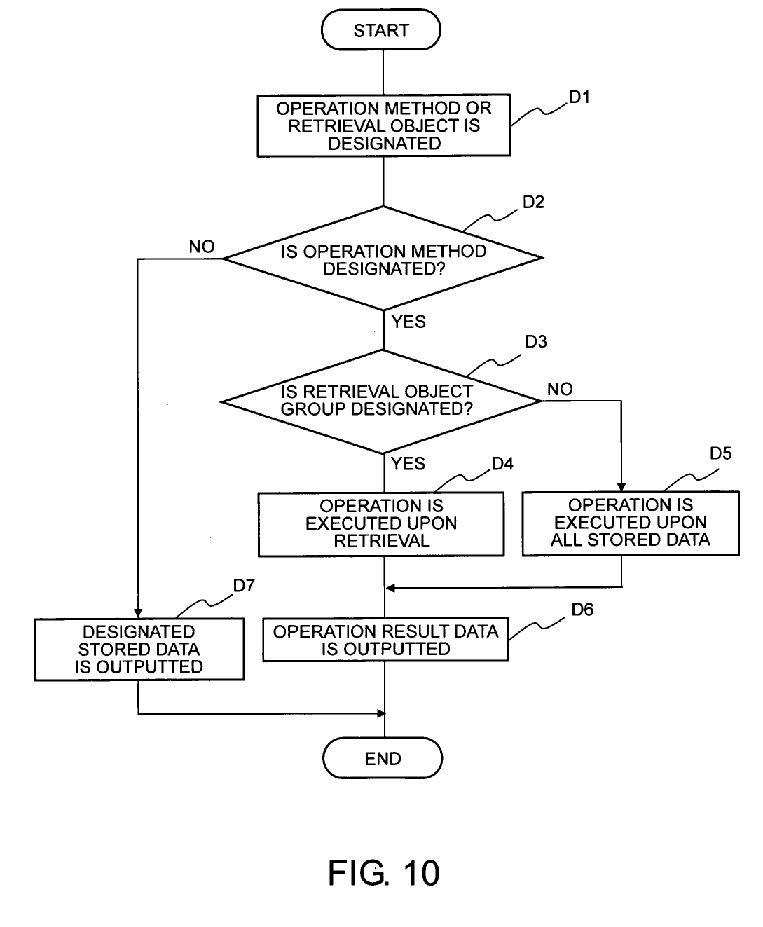

Referring to FIG. 10, the operation of the data processing system 50 according to the fifth embodiment of this invention will be described in detail. It is assumed that the temporary memory 61 stores as the stored data a first word list “I, you, he”, a second word list “I, he, they”, and a third word list “he, she”.

According to the designation by the user, the retrieval object designating section 54 designates the retrieval object (group) among a plurality of items of stored data stored in the temporary memory 61. According to the designation by the user, the operation method designating section 56 designates one of the operation methods including the union set operation, the intersection set operation, the exclusive-OR set operation, the difference set operation, and so on and informs the designated operation method to the data retrieving section 53 (step D1). The operation method designating section 56 may not designate the operation method. In this event (no in step D2), the data retrieving section 53 directly outputs the designated retrieval object (group) (step D7). For example, the stored data “I, you, he” is delivered to the destination application.

In case where a particular operation method is designated (yes in step D2) and the retrieval object group as the operation object is designated (yes in step D3), the data retrieving section 53 delivers the designated retrieval object group and the information designating the operation method to the set operation section 59. The set operation section 59 executes the set operation upon the retrieval object group in accordance with the designated operation method (step D4).

For example, the set operation is executed upon the first word list “I, you, he” and the second word list “I, he, they”. If the union set operation is designated, the set operation section 59 produces the operation result data representative of “I, you, he, they”. If the intersection set operation is designated, the set operation section 59 produces the operation result data representative of “I, he”. Thereafter, the set operation section 59 returns the operation result data to the data retrieving section 53 and the data retrieving section 53 outputs the operation result data (step D6).

In case where a particular operation method is designated (yes in step D2) and the retrieval object group as the operation object is not designated (no in step D3), the data retrieving section 53 reads all items of stored data from the temporary memory 61. Then, the data retrieving section 53 delivers all items of stored data and the information designating the operation method to the set operation section 59. The set operation section 59 executes the set operation upon all items of stored data in accordance with the designated operation method (step D5).

In this case, the set operation is executed upon the first through the third word lists (“I, you, he”, “I, he, they”, “he, she”). If the union set operation is designated, the set operation section 59 produces the operation result data representative of “I, you, he, they, she”. If the intersection set operation is designated, the set operation section 59 produces the operation result data representative of “he”. Thereafter, the set operation section 59 returns the operation result data to the data retrieving section 53 and the data retrieving section 53 outputs the operation result data (step D6).

Although the “character strings” of the words are compared in the above-mentioned example of the set operation, other “attribute values” may be taken into consideration in the manner similar to the fourth embodiment. The “attribute values” taken into consideration upon the set operation are designated by the attribute designating section 55 connected to the set operation section 59. For example, in a plurality of items of presentation data, it is possible to designate a “title” as the “attribute value” and thereafter designate the union set operation. In this manner, it is possible to easily obtain, from the presentation data, data as a combination of title pages alone.

With the data processing system and the data processing method according to the firth embodiment of this invention, it is possible to selectively and easily execute the set operation upon the data transferred between the applications. In order to execute the set operation, it is unnecessary to start a different application for executing the set operation and to transfer the data to the different application. Thus, the number of steps of the set operation process for the data for the list data is reduced. Further, by the set operation, it is possible to add new data to the data transferred between the applications without duplication and to extract necessary data alone from the transferred data. Thus, the information necessary and sufficient for the user is transferred between the applications. In this embodiment, the list data to be transferred is not limited to the word list. As far as the set operation can be executed for the list data, this embodiment is applicable to any list.

### Sixth Embodiment

The data processing system according to each of the first through the fifth embodiments may be implemented by a computer and a computer program. In this case, the data processing operation in the foregoing embodiments is described in the computer program and executed by an arithmetic processing unit (CPU) of the computer.

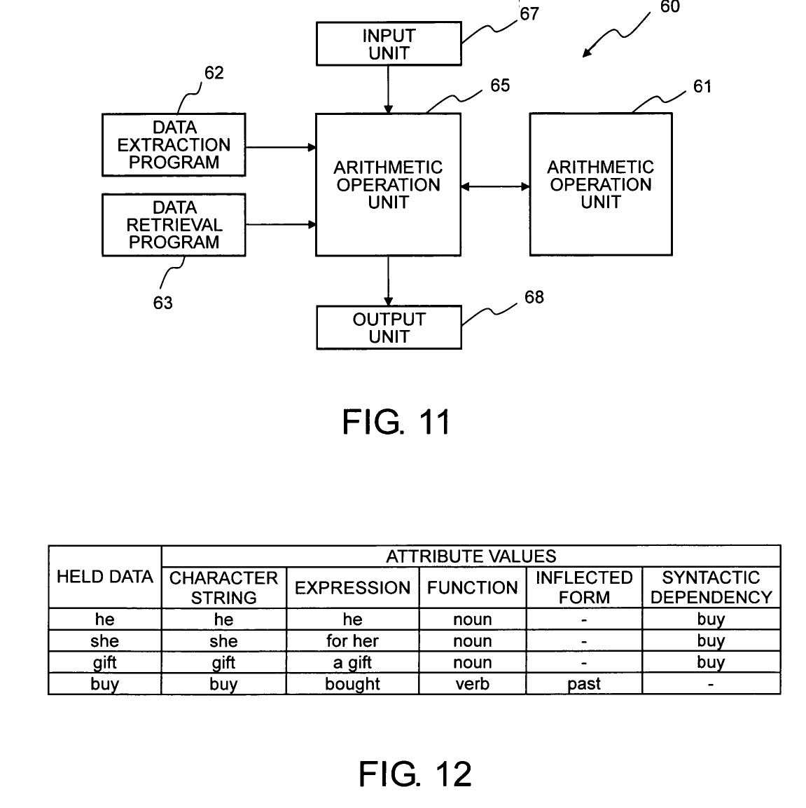

Referring to FIG. 11, a data processing system 60 according to a sixth embodiment of this invention comprises a temporary memory 61, a data extraction program 62, a data retrieval program 63, an arithmetic processing unit 65, an input unit 67, and an output unit 68. The temporary memory 61 is similar to that in the foregoing embodiments and is generally called a clipboard.

The arithmetic processing unit 65 includes a CPU (Central Processing Unit). The input unit 67 may be, for example, a keyboard and a mouse. The output unit 68 may be a display unit. The arithmetic processing unit 65 processes information supplied from the computer programs and the input unit 67, carries out data reading/writing operations upon the temporary memory 61, and controls an output of the output unit 68. For example, with reference to information displayed on the display unit, the user selects desired data to be transferred between applications and the operation method by the use of the mouse. The information designated by the user is supplied to the arithmetic processing unit 65. The arithmetic processing unit 65 executes various processes in accordance with the designation.

The data processing operation in the first through the fifth embodiments is described in the data extraction program 62 and the data retrieval program 63. Specifically, the data extraction program 62 has functions of the data extracting section (12, 22, 32, 42, 52), the attribute designating section (15, 35, 45), the operation method designating section (36, 46), the operation object designating section (47), and the set operation section (39, 49). The attribute designating section, the operation method designating section, and the operation object designating section receive information designated by the user via the input unit 67.

The data retrieval program 63 has functions of the data retrieving section (13, 23, 33, 43, 53), the retrieval object designating section (44, 54), the attribute designating section (25, 55), the operation method designating section (56), and the set operation section (59). The attribute designating section, the operation method designating section, and the retrieval object designating section receive information designated by the user via the input unit 67.

The arithmetic processing unit 65 reads and runs data extraction program 62 and the data retrieval program 63. Data exchange with the temporary memory 61 is executed via the arithmetic processing unit 65. Thus, according to the sixth embodiment, similar effects to those of the foregoing embodiments are obtained.

This invention is applicable to a kana-kanji conversion system, a word processor, a machine translation system, a text mining system, and so on, which mainly deal with words. For example, in a situation where a word list as items of dictionary data is transferred from one application to another application to be used in the latter, the data processing system or the data processing program according to this invention may be used. Further, this invention is applicable to an operating system with a data processing function.

The data to be treated is not limited to the word list. This invention is applicable to any list as far as the set operation can be executed upon list data. For example, a list of image data may be used in the data processing system according to this invention. In this case, the set operation is carried out by judging matching/mismatching with respect to an image format, a resolution, an image size, and so on. As a consequence, it is easy to organize the image data list. Further, in a plurality of items of presentation data, it is possible to designate a title as the “attribute value” and then designate the union set operation. In this manner, it is possible to easily obtain, from the presentation data, data as a combination of title pages alone. Thus, this invention is applicable to an image processing system, a photograph management system, a presentation processing system, and so on.

While this invention has thus far been described in connection with the preferred embodiments thereof, it will be readily possible for those skilled in the art to put this invention into practice in various other manners without departing from the scope set forth in the appended claims.

1. A data processing system (30, 40, 50) comprising:
a memory (61) for storing at least one item of data as stored data;
a data extracting section (32, 42, 52) connected to the memory (61);
a data retrieving section (33, 43, 53) connected to the memory (61); and
a set operation section (39, 49, 59);
the data extracting section (32, 42, 52) extracting first data from data used in a first application;
the set operation section (39, 49, 59) executing a set operation upon the first data and the stored data to produce operation result data representative of a result of the set operation;
the data retrieving section (33, 43, 53) delivering the operation result data to a second application.

2. The data processing system (30) as claimed in claim 1, wherein:
the set operation section (39) is connected to the data extracting section (32);
the data extracting section (32) reading one item of stored data from the memory (61), delivering the first data and the one item of stored data to the set operation section (39), receiving the operation result data from the set operation section (39), and delivering the operation result data to the memory (61);
the data retrieving section (33) reading the operation result data from the memory (61).

3. The data processing system (40) as claimed in claim 1, wherein:
the memory (61) memorizes a plurality of items of stored data;
the set operation section (49) being connected to the data extracting section (42);
the data extracting section (42) reading at least one item of stored data from the memory (61), delivering the first data and the at least one item of stored data to the set operation section (49), receiving the operation result data from the set operation section (49), and delivering the operation result data to the memory (61);
the data retrieving section (43) reading the operation result data from the memory (61).

4. The data processing system as claimed in claim 3, wherein;
the memory (61) stores the operation result data supplied thereto as a new item of stored data in addition to the stored data.

5. The data processing system as claimed in claim 3, wherein:
the memory (61) stores the operation result data supplied thereto in place of the at least one item of stored data.

6. The data processing system as claimed in any one of claims 3 through 5, wherein:
the data extracting section (42) reads, among a plurality of items of stored data, a latest item of stored data and delivers the first data and the latest item of stored data to the set operation section (49).

7. The data processing system as claimed in claim 1, wherein:
the memory (61) stores a plurality of items of stored data;
the set operation section (49) being connected to the data retrieving section (53);
the data extracting section (52) delivering the first data as one of the items of stored data to the memory (61);
the data retrieving section (53) reading multiple items of stored data from the memory (61), delivering the multiple items of stored data to the set operation section (59), receiving the operation result data from the set operation section (59), delivering the operation result data to the second application.

8. The data processing system as claimed in claim 7, wherein:
the data retrieving section (53) reads all items of stored data from the memory (61) and delivers the all items of stored data to the set operation section (59).

9. The data processing system as claimed in claim 1, wherein:
the set operation is one of a union set operation, an intersection set operation, an exclusive-OR set operation, and a difference set operation.

10. The data processing system as claimed in claim 1, further comprising an attribute designating section (35, 45, 55) connected to the set operation section (39, 49, 59);
the attribute designating section (35, 45, 55) designating, as an object of the set operation, one of a plurality of attributes of the stored data.

11. A data processing system (10) comprising:
a memory (61);
a data extracting section (12) connected to the memory (61);
a data retrieving section (13) connected to the memory (61); and
an attribute designating section (15) connected to the data extracting section (12);
the data extracting section (12) extracting first data from held data used in a first application and delivering the first data to the memory (61);
the data retrieving section (13) reading the first data from the memory (61) and delivering the first data to a second application;
the attribute designating section (15) designating, among a plurality of attributes of the held data, at least one attribute of the first data.

12. A data processing system (20) comprising:
a memory (61);
a data extracting section (22) connected to the memory (61);
a data retrieving section (23) connected to the memory (61); and
an attribute designating section (25) connected to the data retrieving section (23);
the data extracting section (22) extracting first data from held data used in a first application and delivering the first data to the memory (61);
the data retrieving section (23) extracting second data from the first data stored in the memory (61) and delivering the second data to a second application;
the attribute designating section (25) designating, among a plurality of attributes of the first data, at least one attribute of the second data.

13. The data processing system as claimed in any one of claims 1, 11, or 12, wherein:
the first data represents a plurality of word.

14. The data processing system as claimed in anyone of claims 11 or 12, wherein:
the first data represents a plurality of words;
the attributes include at least one of a character string of a word, a function of the word, a pronunciation of the word, an inflected form of the word, and a syntactic dependency of the word.

15. A data processing method for a data processing system including a memory for memorizing at least one item of data as stored data, the method comprising the steps of:
(A) extracting first data from data used in a first application;
(B) reading the at least one item of stored data from a memory (61);
(C) executing a set operation upon the first data and the at least one item of stored data;
(D) storing in the memory (61) operation result data representative of a result of the set operation; and
(E) reading the operation result data from the memory (61) and delivering the operation result data to a second application.

16. The data processing method as claimed in claim 15, wherein:
the step (D) of storing the operation result data includes a step of adding the operation result data as a new item of stored data.

17. The data processing method as claimed in claim 15, wherein:
the step (D) of storing the operation result data includes a step of replacing the at least one item of stored data by the operation result data.

18. A data processing method for a data processing system including a memory for memorizing a plurality of items of stored data, the method comprising the steps of:
(F) extracting first data from data used in a first application;
(G) storing the first data in a memory (61) as one of a plurality of items of stored data;
(H) reading multiple items of stored data from the memory (61);
(I) executing a set operation upon the multiple items of stored data read in the step (H); and
(J) delivering to a second application operation result data representative of a result of the set operation.

19. The data processing method as claimed in any one of claims 15 through 18, further comprising:
the step (Z) of designating, among a plurality of attributes of the stored data, an attribute as an object of the set operation.

20. A data processing method for a data processing system including a memory for memorizing at least one item of data as stored data, the method comprising the steps of:
(K) designating at least one attribute among a plurality of attributes of held data used in a first application;
(L) extracting from the held data first data having the at least one attribute;
(M) storing the first data in a memory (61); and
(N) reading the first data stored in the memory (61) and delivering the first data to a second application.

21. A data processing method for a data processing system including a memory for memorizing at least one item of data as stored data, the method comprising the steps of:
(O) extracting first data from held data used in a first application;
(P) storing the first data in a memory (61);
(Q) designating at least one attribute among a plurality of attributes of the first data;
(R) extracting from the first data stored in the memory (61) second data having the at least one attribute; and
(S) delivering the second data to a second application.

22. A data processing program for use in a data processing system, the data processing system including a memory (61) for storing at least one item of data as stored data and an arithmetic operation unit (65) connected to the memory (61), the data processing program making the arithmetic operation unit (65) execute:
(a) extracting first data from data used in a first application;
(b) reading the at least one item of stored data from the memory (61);
(c) executing a set operation upon the first data and the at least one item of stored data;
(d) storing in the memory (61) operation result data representative of a result of the set operation; and
(e) reading the operation result data from the memory (61) and delivering the operation result data to a second application.

23. The data processing program as claimed in claim 22, wherein:
the step (d) of storing the operation result data includes a step of adding the operation result data as a new item of stored data.

24. The data processing program as claimed in claim 22, wherein:
the step (d) of storing the operation result data includes a step of replacing the at least one item of stored data by the operation result data.

25. A data processing program for use in a data processing system, the data processing system including a memory (61) for storing at least one item of data as stored data and an arithmetic operation unit (65) connected to the memory (61), the data processing program making the arithmetic operation unit (65) execute:
(f) extracting first data from data used in a first application;
(g) storing the first data in the memory (61) as one of a plurality of items of stored data;
(h) reading multiple items of stored data from the memory (61);
(i) executing a set operation upon the multiple items of stored data read in the step (H); and
(j) delivering to a second application operation result data representative of a result of the set operation.

26. The data processing program as claimed in any one of claims 22 or 25, the data processing program making the arithmetic operation unit (65) further execute:
the step (z) of designating, among a plurality of attributes of the stored data, an attribute as an object of the set operation.

27. A data processing program for use in a data processing system, the data processing system including a memory (61) for storing at least one item of data as stored data and an arithmetic operation unit (65) connected to the memory (61), the data processing program making the arithmetic operation unit (65) execute:
(k) designating at least one attribute among a plurality of attributes of held data used in a first application;
(l) extracting from the held data first data having the at least one attribute;
(m) storing the first data in the memory (61); and
(n) reading the first data stored in the memory (61) and delivering the first data to a second application.

28. A data processing program for use in a data processing system, the data processing system including a memory (61) for storing at least one item of data as stored data and an arithmetic operation unit (65) connected to the memory (61), the data processing program making the arithmetic operation unit (65) execute:
(o) extracting first data from held data used in a first application;
(p) storing the first data in the memory (61);
(q) designating at least one attribute among a plurality of attributes of the first data;
(r) extracting from the first data stored in the memory (61) second data having the at least one attribute; and
(s) delivering the second data to a second application.
